(19) United States
(12) Patent Application Publication
(10) Pub. No.: US 2026/0333613 A1
(43) Pub. Date: Oct. 22, 2026

(54) MODULAR FAULT MANAGED POWER CONTROLLERS FOR COMMUNICATION SYSTEMS

(71) Applicant: Outdoor Wireless Networks LLC, Claremont, NC (US)

(72) Inventor: Thomas F. CRAFT, Jr., Murphy, TX (US)

(21) Appl. No.: 19/099,658

(22) PCT Filed: Sep. 7, 2023
(86) PCT No.: PCT/US2023/073615

§ 371 Date: Jan. 29, 2025

Related U.S. Application Data
(60) Provisional application No. 63/404,402, filed on Sep. 7, 2022.
(60) Provisional application No. 63/404,498, filed on Sep. 7, 2022.

(51) Int. Cl. H05K 7/18; H02H 7/12; H02H 7/125; H02H 9/02; H02J 9/06; H02M 3/00; H02M 7/00; H05K 7/14

(52) U.S. Cl. CPC H05K 7/186; H02H 7/1213; H02H 7/125; H02H 9/02; H02J 9/061; H02M 3/003; H02M 7/003; H05K 7/1424

(57) ABSTRACT

A modular fault managed power controller, which may include at least two fault managed power modules each configured to provide fault managed power to respective subsets of a plurality of small cell base stations. The small cell base stations may be provided in a variety of configurations and receive data via a communication or data network, which may be or may include a backhaul network for a cellular network, a hybrid-fiber-coax (HFC) network, or a passive optical network (PON).

### CROSS-REFERENCE TO RELATED APPLICATIONS

The present application claims the benefit of priority to U.S. Provisional Application No. 63/404,402 and U.S. Provisional Application No. 63/404,498, both filed on Sep. 7, 2022, and the entire contents of each above-identified application are incorporated by reference as if set forth herein.

### TECHNICAL FIELD

Aspects of the present disclosure relate generally to communications systems and, more particularly, to power supply systems for communication systems.

### BACKGROUND

Fault managed power systems (FMP or FMPS) are power systems that include monitoring and fault detection capabilities. Such capabilities may be configured to monitor conductors in cables, and detect faults that indicate likely human or animal contact with the cable conductors. The FMP system may then take appropriate action, such as automatically and immediately removing power from the conductors. This detection and action, when performed with a sufficiently fast response time, may limit an amount of current (if any) that passes through a human or animal body to a level that prevents the human or animal from experiencing ventricular fibrillation. This may maintain so-called “touch-safe” operation. Other faults that may be prevented include line-to-line shorts and line-to-ground shorts, which have a capacity to start electrical fires and damage electronic equipment. FMP systems are being increasingly considered for Class 4 power supplies, having voltage levels in the hundreds of volts (and power levels in kilowatt ranges), exceeding existing Class 2 power supplies.

One potential area for use of fault managed power systems is in powering communications equipment. For example, and as discussed in U.S. Pat. No. 10,770,203, the entirety of which is incorporated by reference herein, data traffic has increased by about 4,000 percent over the last decade, and is expected to continue increasing at a rate of over 50% per year for at least the next several years.

Cellular operators are beginning to deploy 5G cellular networks in an effort to support the increased cellular data traffic with better coverage and reduced latency. One expected change in the cellular architecture that is anticipated with the deployment of 5G networks is a rapid increase in the number of so-called small cell base stations that are deployed. Generally speaking, a “small cell” base station refers to an operator-controlled, low-power radio access node that operates in the licensed spectrum and/or that operates in the unlicensed spectrum but provides operator-grade WiFi connectivity. The term “small cell” encompasses microcells, picocells, femtocells and metrocells that support communications with fixed and mobile subscribers that are within between about 10 meters and 300-500 meters of the small cell base station depending on the type of small cell used. The term small cell generally does not encompass in-building solutions such as distributed antenna systems that are typically implemented as part of the macrocell layer of a cellular network.

Small cell base stations are typically deployed within the coverage area of a base station of the macrocell network, and the small cell base stations are used to provide increased throughput in high traffic areas within the macrocell. This approach allows the macrocell base station to be used to provide coverage over a wide area, with the small cell base stations supporting much of the capacity requirements in high traffic areas within the macrocell. In heavily-populated urban and suburban areas, it is anticipated that more than ten small cells will be deployed within a typical 5G macrocell in order to support the increased throughput requirements. As small cell base stations have limited range, they must be located in close proximity to users, which typically requires that the small cell base stations be located outdoors, often on publicly-owned land such as along streets. Typical outdoor locations for small cell base stations include lamp posts, utility poles, street signs and the like, which are locations that either do not include an electric power source, or include a power source that is owned and operated by an entity other than the cellular network operator. A typical small cell base station may require between 200-1,000 Watts of power. As small cell base stations are deployed in large numbers, providing electric power to the small cell base station locations represents a significant challenge.

### SUMMARY

According to some embodiments of the present inventive concepts, a power supply system may include a rack shelf; and at least one card that is configured to be installed in the rack shelf, the at least one card having at least one fault managed power circuit therein.

In some embodiments, the rack shelf may include a plurality of openings, and the at least one card may be dimensioned to be received in a respective opening of the plurality of openings.

In some embodiments, a total number of the openings of the rack shelf may exceed a number of cards installed in the rack shelf.

In some embodiments, each of the at least one cards may be configured to receive a first power signal from the rack shelf and provide a second power signal to at least one respective telecommunications component.

In some embodiments, the first power signal may be a DC power signal.

In some embodiments, the second power signal may be provided to at least one small cell base station.

In some embodiments, the at least one card may include a high resistance midpoint ground (HRMG) device or circuit.

In some embodiments, the at least one card may include a surge suppression device or circuit.

In some embodiments, a first card of the at least one card may include a plurality of fault managed power circuits.

In some embodiments, the power supply system may further include a controller configured to control operation of the fault managed power circuits.

In some embodiments, the rack shelf is two rack units in height.

In some embodiments, the at least one card may include a first connector, and the rack shelf may include a second connector configured to mate with the first connector.

In some embodiments, the rack shelf and/or the at least one card may include a barrier interlock.

According to some embodiments of the present inventive concepts, a power supply system may include a rack shelf having a plurality of openings; and a plurality of fault managed power cards installed in respective openings in the rack shelf, with each fault managed power card comprising at least one fault managed power circuit.

In some embodiments, a total number of the plurality of openings may exceed a total number of the plurality of fault managed power cards installed in the rack shelf.

In some embodiments, an input to the power supply system may be on a rear or back surface of the rack shelf, and the outputs from the power supply system are on or proximate to a front or forward surface of the rack shelf.

In some embodiments, the power supply system may further include a controller configured to control operation of the fault managed power circuits, and the controller may include a communication interface.

According to some embodiments of the present inventive concepts, a modular fault managed power controller may be provided, which may include at least two fault managed power modules each configured to provide fault managed power to respective subsets of a plurality of small cell base stations.

According to some embodiments of the present inventive concepts, a modular fault managed power controller may be provided, which may at least one fault managed power module and a barrier interlock configured to disable or disrupt power input to and/or output from the at least one fault managed power module.

According to some embodiments of the present inventive concepts, a communication system may include a power supply system and/or a modular fault managed power controllers as provided herein.

According to some embodiments of the present inventive concepts, a power supply system may include an AC to DC converter having an input tied to a main power supply and an output tied to a first side of a bus; and a shelf providing fault managed power tied to a second side of the bus and configured to supply power to a cluster of small cell base stations.

In some embodiments, the power supply system may further include a DC to DC converter on the second side of the bus and configured to boost a voltage of a power signal on the bus to a higher voltage input to the shelf.

The present disclosure is not limited to the above provided examples of embodiments, and other embodiments of the present inventive concepts will be provided herein.

### BRIEF DESCRIPTION OF THE DRAWINGS

FIG. 1 is a perspective view of some components of a power supply system according to some embodiments of the present disclosure.

FIG. 2 is a block diagram of some components of a power supply system according to some embodiments of the present disclosure.

FIG. 3 is a block diagram of a power source installation that may be used to implement power sourcing equipment devices according to some embodiments of the present disclosure.

FIGS. 4-6 provide block diagrams showing arrangements of power equipment in power plants according to some embodiments of the present disclosure.

FIGS. 7A and 7B show installations of small cell base station antennas, according to some embodiments of the present inventive concepts.

FIGS. 8A, 8B, and 8C provide block diagrams showing arrangements of power equipment in power plants according to some embodiments of the present disclosure.

FIG. 9 illustrates an example of a hybrid-fiber-coax (HFC) network.

FIG. 10 shows an example of a HFC network in which small cells may be provided, according to some embodiments of the present disclosure.

FIG. 11 is a block diagram showing an arrangement of power equipment in power plants according to some embodiments of the present disclosure.

FIG. 12 shows an example of a passive optical network (PON) in which small cells may be provided according to some embodiments of the present disclosure.

Like reference numerals refer to corresponding parts throughout the drawings. Moreover, multiple instances of the same part may be designated by a common prefix separated from an instance number by a dash.

### DETAILED DESCRIPTION

When deploying a new macrocell base station, a cellular operator will typically work with the local electric utility company to arrange to have alternating current (“AC”) power provided to the site from the local electric power grid. While this process may be both time-consuming and expensive, the time required to plan, build and deploy a new macrocell base station may be as long as two years, allowing sufficient time for coordinating with the electric utility company, obtaining necessary permitting from local government agencies, and then having the local electric utility company deploy the connection to the electric power grid in order to deliver power to the site. Moreover, the cost associated with providing power to the macrocell base station, which may be on the order of $5,000 to $20,000, can readily be absorbed by a macrocell base station that serves thousands of users. Thus providing electric power to macrocell base stations has not raised major issues for cellular network operators.

Unfortunately, however, the model for delivering electric power to macrocell base stations does not work well with small cell deployments, where the cellular network operator typically needs to deploy small cell base stations quickly and in a cost-effective manner. In order to meet these goals, cellular operators require a repeatable process for delivering electric power to small cell base station locations that preferably does not require involvement of third parties such as electric utility companies.

One solution that has been proposed for powering small cell base stations is the use of composite power-data cables. Composite power-data cables may allow a cellular network operator to deploy a single cable between a hub and a small cell base station that provides both electric power and backhaul connectivity to the small cell base station. The hub may be, for example, a central office, a macro cell base station or some other network operator owned site that is connected to the electric power grid. All cellular base stations must have some sort of backhaul connection to the core network, and with small cell base stations the backhaul connection is typically implemented as a fiber optic cabling connection. Since the cellular network operator already would typically deploy a fiber optic cable to a new small cell base station installation, changing the fiber optic cable to a power-plus-fiber cable that includes both power conductors and optical fibers provides a relatively low cost solution for also providing an electric power connection to the new small cell base station, particularly as the installation costs associated with installing a new cabling connection between a hub and the new small cell base station will typically exceed, and often far exceed, the additional cost associated with adding power conductors to the fiber optic cable. For example, the incremental cost of deploying (installing) a power-plus-fiber cable as compared to deploying a fiber optic cable is less than $1/foot, while the cost of deploying cables in the outside plant are on the order of $1.50/foot to $6/foot in typical installations. Moreover, in urban areas-which is one of the most common locations where new small cell base stations are being deployed-the cables often must be installed underground beneath concrete or asphalt surfaces. In such environments, the installation costs can be as high as $30-40/foot or even more.

U.S. Pat. No. 10,770,203 provides power and data connectivity micro grids for information and communication technology infrastructure including small cell base stations. These power and data connectivity micro grids may be owned and controlled by cellular network operators which allows the cellular network operators to more quickly and less expensively provide power and data connectivity (backhaul) to new small cell base stations. As explained by the '203 patent, the network of composite power-data cables (and the sourcing equipment supplying the network of composite power-data cables with power and data capacity) may be designed to have power and data capacity far exceeding the capacity requirements of existing nodes along the micro grid. Because such excess capacity is provided, when new remote network-connected devices are installed in the vicinity of a micro grid, composite power-data cables can be routed from tap points along the micro grid to the location of the new remote network-connected device (e.g., a new small cell base station). The newly installed composite power-data cables may themselves be over-provisioned and additional tap points may be provided along the new composite power-data cabling connections so that each new installation may act to further extend the footprint of the micro grid.

Although such excess capacity is desirable in some situations, modularity and flexibility may be desirable in others, for example when purchasing, installing, and configuring power sourcing equipment that provides, e.g., fault managed power. For example, such over-provisioning may result in a fault managed power system being used that may be configured (or licensed for) a maximum number of small cell base stations or other components that can be connected to the fault managed power system, even though the total number of small cell base stations is far less than the maximum. Such situations may be cost-prohibitive.

Accordingly, some aspects of the present disclosure provide a power supply system that provides fault managed power in a more modular fashion. The power supply system may include a rack shelf, and may include at least one fault managed power card configured to be installed in the rack shelf. Each of the fault managed power cards may be configured to receive a first power signal from the rack shelf and provide a second power signal to at least one respective telecommunications component. In some embodiments, the rack shelf may include a plurality of openings each configured to receive a respective fault managed power card. In some embodiments, the rack shelf may have a total number of such openings that exceeds a number of fault managed power cards installed in the rack shelf.

Aspects of the present disclosure are also based on the contemplation of potentially higher efficiency arrangements of components that provide power to small cell base stations and other communications equipment using fault managed power (FMP) controllers, such as modular fault managed power controllers, to provide monitoring and fault detection capabilities in power supply networks for communication equipment.

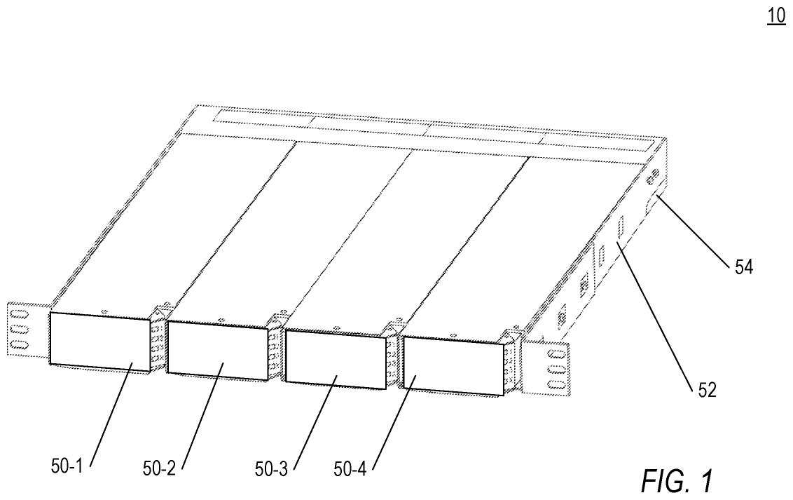

FIG. 1 is a perspective view of some components of the power supply system of the present disclosure, according to some example embodiments. As best seen in FIG. 1, a power supply system 10 may include a rack shelf 52, which may include openings therein each configured to receive one of a plurality of modules or cards 50 (e.g., card 50-1, 50-2, 50-3, or 50-4). The rack shelf 52 and the cards 50 received therein may be two rack units (2U, approximately 3.5 inches) in height and approximately 12 inches deep, with the understanding that the present disclosure is not limited thereto. The rack shelf 52 may be dimensioned in length and width to be received into a standard frame or rack within an electrical enclosure. In some embodiments, inputs to the shelf 52 may be provided on a rear surface of the shelf 52, and outputs from the shelf 52 (e.g., outputs from the cards 50) may be provided on or proximate to the front surface of the shelf 52). Each card 50 may include a connector (not shown) that mates with a respective connector (not shown) present in the rear of the shelf 52. The connectors may include power and/or data connections.

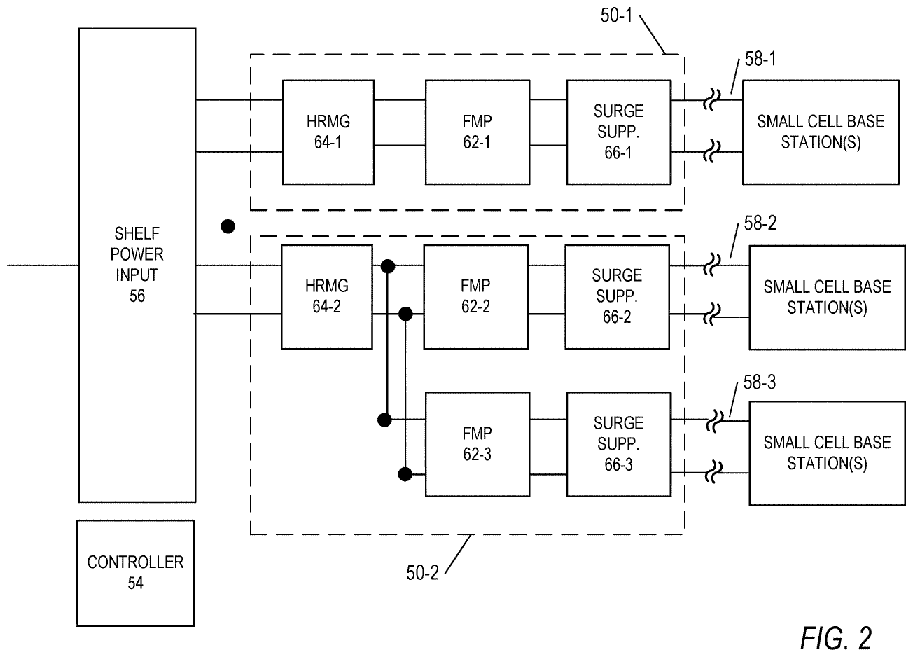

The shelf 52 may be a GR3108 class 2 shelf capable of receiving multiple cards 50 installed therein. The shelf 52 may include an input interface 56 (see FIG. 2) that receives a direct current (DC) power input, such as 380V DC. In some embodiments, the shelf 52 may receive the power input as alternating current (AC) that is converter to DC power by an AC-to-DC converter (not shown) including, for example, in shelf power input 56. In some embodiments, the shelf 52 may receive the power input from a rectifier, converter, or power supply (not shown) mounted adjacent to the shelf 52 in a rack (not shown) and coupled to the shelf 52 via a bus bar or other conductive component.

As best seen in the simplified block diagram of FIG. 2, which only shows two cards 50, each card 50 (e.g., card 50-1 of FIG. 2) may include one or more fault managed power (FMP) circuits 62 therein. Each of the cards 50 may be tied to the input of the shelf 52 (e.g., each may receive the 380V DC power input discussed above). For example, some embodiments (e.g., card 50-1) may have one input and one output, which may provide a total output capacity of the card 50-1 (e.g., 25 amps (A)). In some embodiments the card 50 (e.g., card 50-2) may include two outputs which share the total output capacity of the card 50-2 (e.g., a first output may provide a first 12.5 A, and a second output may provide a second 12.5 A).

Each card 50 may include fault managed power (FMP) circuits 62 (as defined by ATIS 0600040 and UL 1400-1). In some embodiments, there may be a respective FMP circuit 62 for each output 58 of the system 10. Each card 50 may include a High Resistance Midpoint Ground (HRMG) device 64, which may be configured to create positive and negative voltage signals (e.g., +/'190 VDC) from the input voltage (e.g., 380V DC) provided by the shelf power input 56. In some embodiments, each card 50 and/or output 58 thereof may be equipped with a surge suppression device 66. The number and order of the FMP circuits, HRMG devices 64, and surge suppression devices 66 may differ from that shown in FIG. 2.

In some embodiments, the rack shelf 52 may include a controller 54, which may be a common controller 54 that controls operations of the each of the installed cards 50. In some embodiments, the controller 54 may be an edge controller. The controller 54 may be configured to manage the FMP circuits on each card 50. The controller 54 may include a processor and memory that stores commands or instructions executable by the processor. The controller 54 may include a communication interface (e.g., modem, network port, or the like) that enable communication with one or more remote devices and/or networks. In some embodiments, a plurality of input controls may be present, for example each respectively controlling an output of the system. Status indicators, e.g., light emitting diodes may be present to visually indicate the connection status and/or power status of each output from the cards 50 and/or rack 52.

In some embodiments, the rack shelf 52 and/or the cards 50 thereof may include interlock equipped barriers or barrier interlocks (not shown). The controller 54 and/or cards 50 may be configured to disable or disrupt power output by one or more of the cards 50 if a barrier interlock is breached. For example, an external door, shield, or cover may be provided on a front surface or back surface of the rack shelf 52, which if manipulated in an unauthorized or unexpected fashion, may disable or disrupt power output by one or more of the cards 50 and/or power input to the rack shelf 52. In some embodiments, an authorization may be communicated to the controller 54 (e.g., by a remote device communicatively coupled to the controller 54) to communicate to the controller 54 that a technician is authorized to breach the barrier interlock without disabling of the power input and/or output by the rack shelf 52 or the cards 50 installed therein.

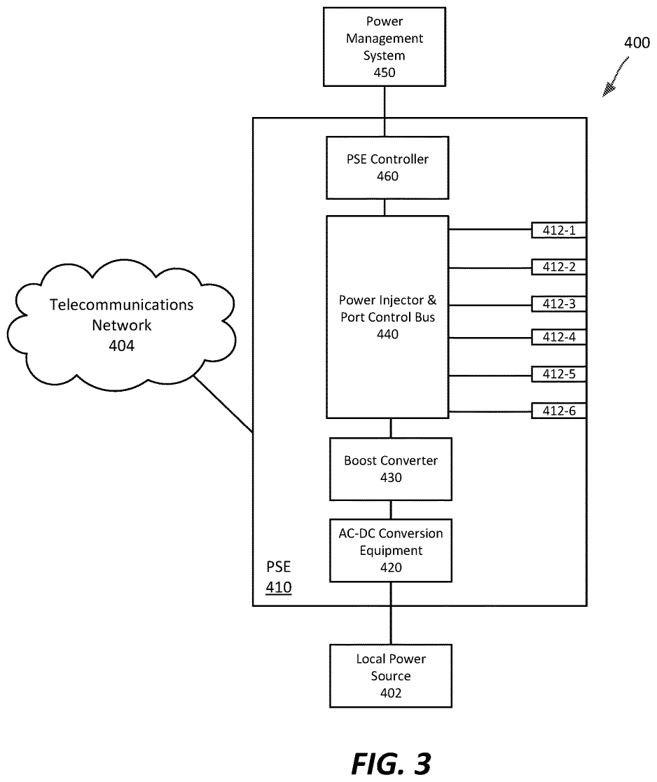

FIG. 3 is a schematic block diagram illustrating a power source installation 400 that may be used to implement power sourcing equipment devices. As shown in FIG. 3, the power source installation 400 may include a local power source 402 and a power sourcing equipment device 410 that includes a plurality of hybrid power-data ports 412 (or, alternatively, separate power ports and data ports). The power sourcing equipment device 410 may comprise one or more transformers, converters and/or power conditioners that convert AC or DC supplied power received from the local power source 402 into DC power that is provided at the hybrid power-data ports 412. The power source installation 400 may also have connections to a telecommunications network 404 such as, for example, a core network of the cellular network operator. The local power source 402 will typically comprise a connection to utility-provided AC power, although other local power sources may be used. The power sourcing equipment device 410 may include AC-DC power conversion equipment 420 that converts the AC power into a plurality of DC power signals that may be output through the hybrid power-data ports 412 (or through separate power data ports). In some embodiments, the power sourcing equipment device 410 may further include a boost converter 430 that steps up the voltage of the DC power signals to a desired level such as, for example, 380 V. In some cases, the stepped up voltage level may be between 260-1500 V DC. Increasing the voltage of the DC power signal reduces the current levels, which may reduce I²R power losses as the power signals are delivered to remote powered devices (e.g., small cell base stations) via power-plus-data cables that are connected to the hybrid power-data ports 412.

The power sourcing equipment device 410 further includes a power injector and port control bus 440 that is coupled to the output of the boost converter 430 or the output of the AC-DC conversion equipment 420 if the boost converter 430 is not included on the power sourcing equipment device 410. The power injector and port control bus 440 may be configured to selectively inject DC power onto the electrical conductor pairs included in the hybrid power-data ports 412 in order to inject DC power onto the power-plus-fiber cables that are connected to the respective hybrid power-data ports 412 (or through separate power data ports). A power management system 450 may also be part of the power source installation 400, and may be internal or external to the power sourcing equipment device 410. The power management system 450 may manage power delivery to remote power devices by enabling and disabling the hybrid power-data ports 412 of the power sourcing equipment device 410. The power sourcing equipment device 410 may include the power supply system 10 of FIG. 1 or the modules or cards 50 thereof.

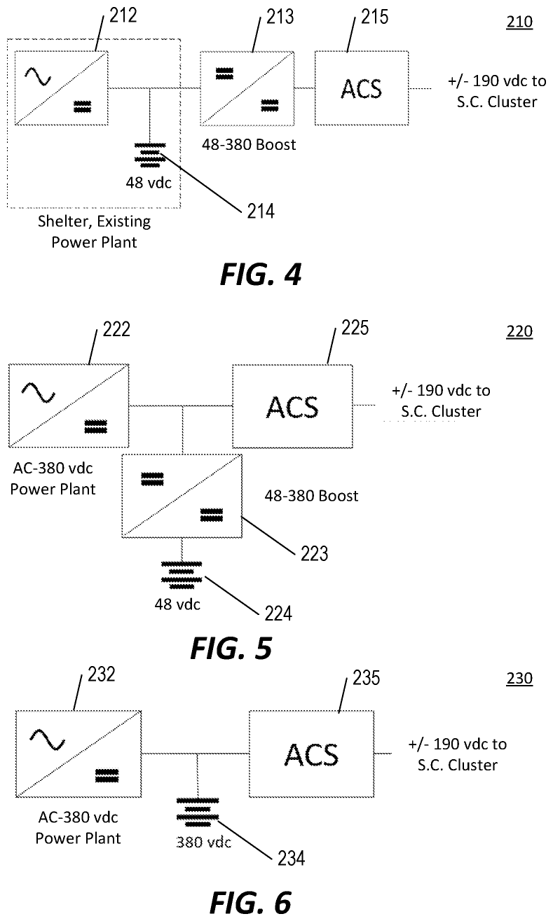

FIGS. 4-6 provide block diagrams 210, 220, and 230, showing arrangements of power equipment in power plants (e.g., locations where power signals may be generated for communications equipment). In FIG. 4, for example, an AC to DC converter 212 may provide a 48 VDC (or −48 VDC) signal to a bus tied to a 48V battery backup 214. The bus may be tied to a DC-DC converter 213 that boosts the signal from 48V to 380V. An auxiliary controller shelf (ACS) and/or other power management circuit 215 may receive the boosted signal and output a signal (e.g., a +/−190 V DC signal) resulting from a high resistance midpoint ground (HRMG) circuit or device. In some embodiments, the ACS 215 may be or may include the power supply system 10 of FIG. 1 or a module or card 50 thereof. The power plant of FIG. 4 may be used, e.g., in shelters and/or with higher efficiency rectifiers in a cabinet, and may provide interoperability with existing rectifier power plants while adding or enabling energy management and green initiatives. For example, the power plant of FIG. 2 may increase efficiency by 2-3 % and lower cost and reduce power plant size.

In FIG. 5, for example, an AC to DC converter 222 may provide a 380 VDC signal to a bus. A 48V battery backup 224 may be tied to the bus via a bidirectional DC-DC converter 223 that converts the signal between 48V and 380V. An ACS and/or other power management circuit 225 may receive the boosted signal and output a signal (e.g., a +/−190 V DC signal) resulting from a high resistance midpoint ground (HRMG) circuit or device. In some embodiments, the ACS 225 may be or may include the power supply system 10 of FIG. 1 or a module or card 50 thereof. The power plant of FIG. 5 may not provide size benefits over that of FIG. 4, but may improve efficiencies, as only power transmitted between the backup battery and the bus needs to be converted from 48V to 380V (or vice versa).

In FIG. 6, for example, an AC to DC converter 232 may provide a 380 VDC signal to a bus, which is tied to a 380V battery backup 234. An ACS and/or other power management circuit 235 may receive the boosted signal and output a signal (e.g., a +/−190 V DC signal) resulting from a high resistance midpoint ground (HRMG) circuit or device. In some embodiments, the ACS 235 may be or may include the power supply system 10 of FIG. 1 or a module or card 50 thereof. The power plant of FIG. 6 may provide size benefits over that of FIG. 4 and FIG. 5, and may also improve efficiencies, but at the added expense of a higher voltage battery.

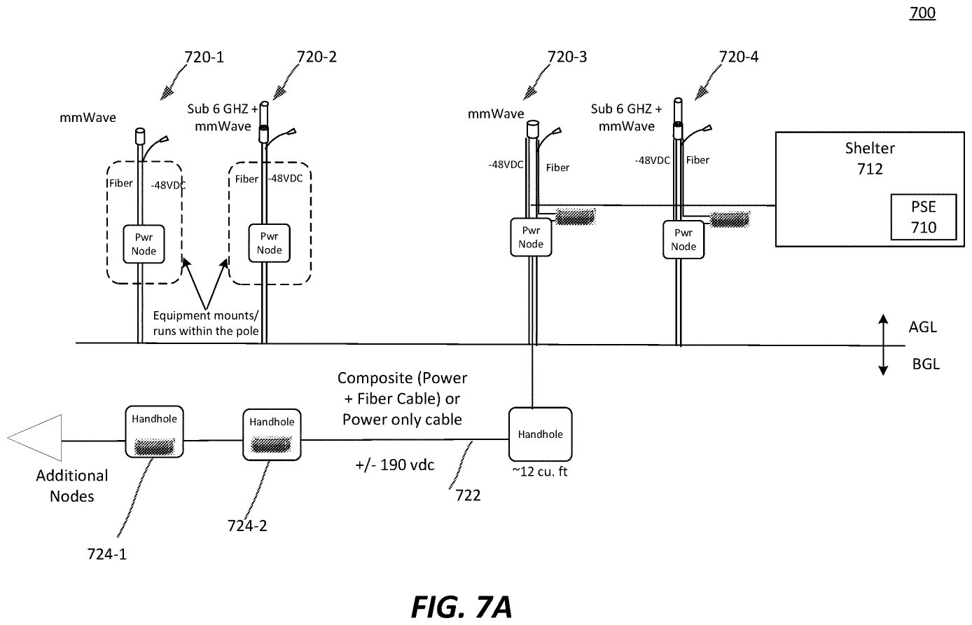

FIGS. 7A and 7B show installations 700 and 750, respectively, according to some embodiments of the present inventive concepts. As seen in FIG. 7A, in some embodiments an existing shelter 710, which may be at a base of or proximate to a macrocell cellular tower, may be retrofitted with power sourcing equipment 710, which may provide power (via a dedicated power line or a composite cable carrying both power and fiber) to small cell sites 720 (e.g., first site 720-1, second site 720-2, and so on). In some embodiments, the power-carrying cable 722 may transition from above ground level (AGL) to below ground level (BGL), or from BGL to AGL, for example via a handhole. Splice boxes or enclosures 724 may be provided to offer transitions from a trunk cable to a cell-specific cable. The power sourcing equipment 710 may include one or more of the components discussed above with respect to FIGS. 1-6.

As seen in FIG. 7B, in some embodiments a power hub 760, which may be installed in the field, may have therein power sourcing equipment 710, which may provide DC power from an AC source 762 to small cell sites 720 (e.g., first site 720-1, second site 720-2, and so on) e.g., via a dedicated power line or a composite cable carrying both power and fiber). In some embodiments, the power-carrying cable 722 may transition from above ground level (AGL) to below ground level (BGL), or from BGL to AGL, for example via a handhole. Splice boxes or enclosures 724 may be provided to offer transitions from a trunk cable to a cell-specific cable. The power hub 760 may include one or more of the components discussed above with respect to FIGS. 1-6.

There is also increasing interest in deploying networks of small cell base stations in existing hybrid-fiber-coax (HFC) networks, which are used by some multiple system operators (MSOs), such as cable television systems. In an HFC network, data travels downstream (e.g., to homes or customer sites) through a fiber optic backbone, which can carry relatively large amounts of information over relatively long distances with relatively minimal signal loss. At a transition site called an optical node, an optical-to-electrical conversion is performed, and the resulting electrical signal is carried to the homes or customer sites using coaxial cables, which may enable relatively cost-efficient data transmission over a final transmission link.

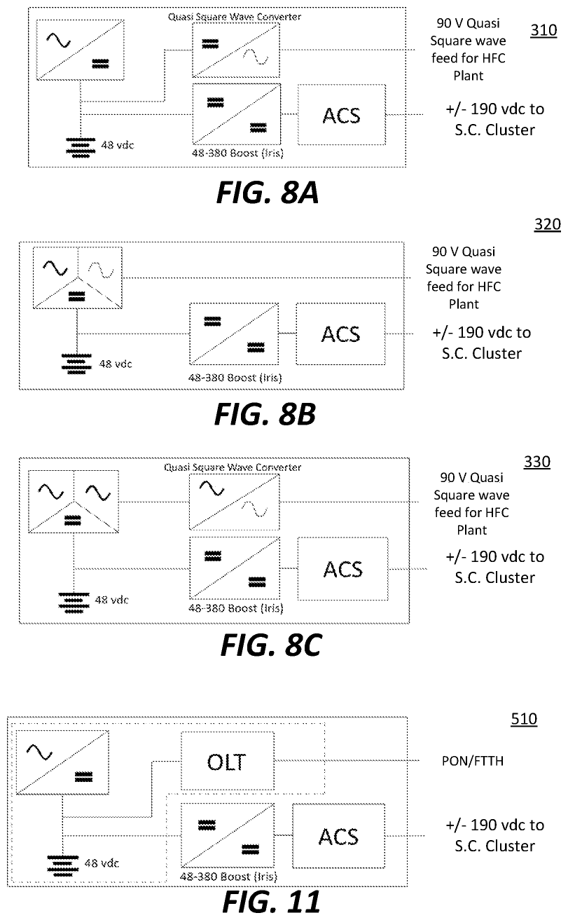

FIG. 9 illustrates an example of a HFC network 800, optical node 810, and subscriber/customer premises 820. Powered devices, such as splitters and/or converters, in HFC networks may use a quasi-square wave power signal such as a 90V quasi-square wave signal. In some embodiments of the present disclosure, a power plant may include a quasi square wave generator for an HFC network.

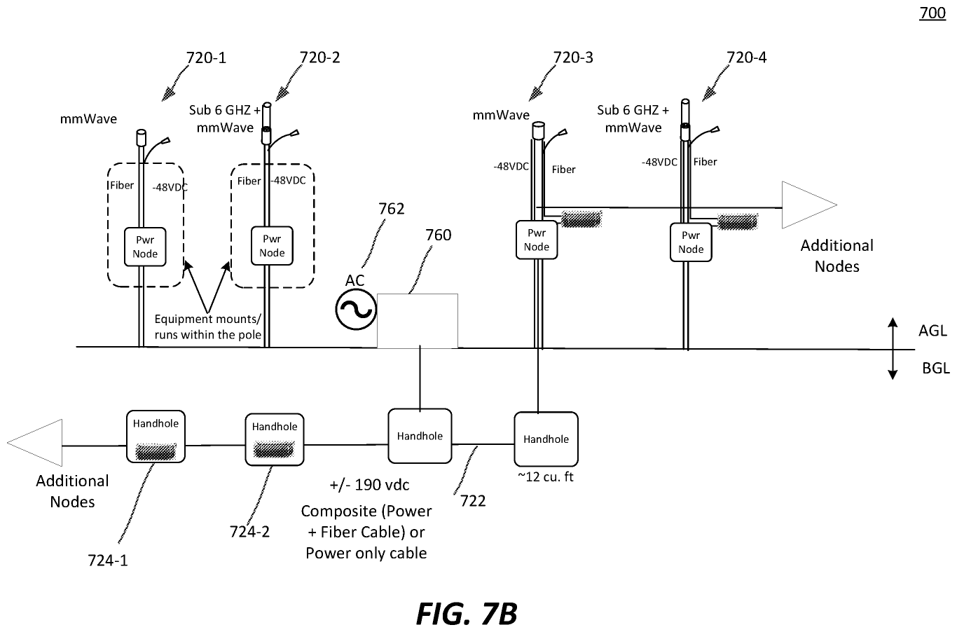

FIGS. 8A, 8B, and 8C provide block diagrams 310, 320, and 330, respectively showing arrangements of power equipment in power plants (e.g., locations where power signals may be generated for communications equipment that includes small cell base stations and HFC equipment). In FIG. 8A, for example, an AC to DC converter may provide a 48 VDC (or −48 VDC) signal to a bus tied to a 48V battery backup. The bus may be tied to a DC-DC converter that boosts the signal from 48V to 380V. An ACS and/or other power management circuit may receive the boosted signal and output a signal (e.g., a +/−190 V DC signal) resulting from a high resistance midpoint ground (HRMG) circuit or device to the small cell base stations. Additionally, a DC to quasi-square wave generator may be tied to the 48V bus and may generate a quasi-square wave to power the HFC equipment.

In FIG. 8B, for example, a converter may have an AC input and two outputs, a quasi-square wave output that may generate a quasi-square wave to power the HFC equipment, and a DC output configured to provide a 48 VDC (or −48 VDC) signal to a bus. The bus may be tied to a 48V battery backup and a DC-DC converter (e.g., a unidirectional DC-DC converter) that converts the signal from 48V to 380V. An ACS and/or other power management circuit may receive the boosted signal and output a signal (e.g., a +/−190 V DC signal) resulting from a high resistance midpoint ground (HRMG) circuit or device.

In FIG. 8C, for example, a converter may have an AC input and two outputs, an AC output and a DC output. The AC output may be tied to quasi-square wave generator that may generate a quasi-square wave to power the HFC equipment, and the DC output may be configured to provide a 48 VDC (or −48 VDC) signal to a bus. The bus may be tied to a 48V battery backup and a DC-DC converter (e.g., a unidirectional DC-DC converter) that converts the signal from 48V to 380V. An ACS and/or other power management circuit may receive the boosted signal and output a signal resulting from a high resistance midpoint ground (HRMG).

The arrangements of FIGS. 8A-C may enable the aggregation of small cells (small cell base stations) into an HFC network, and may use a hybrid cable to deliver both power to the small cells and HFC equipment and fiber (data) to the small cells and to MSO subscribers. Energy management control may also be provided.

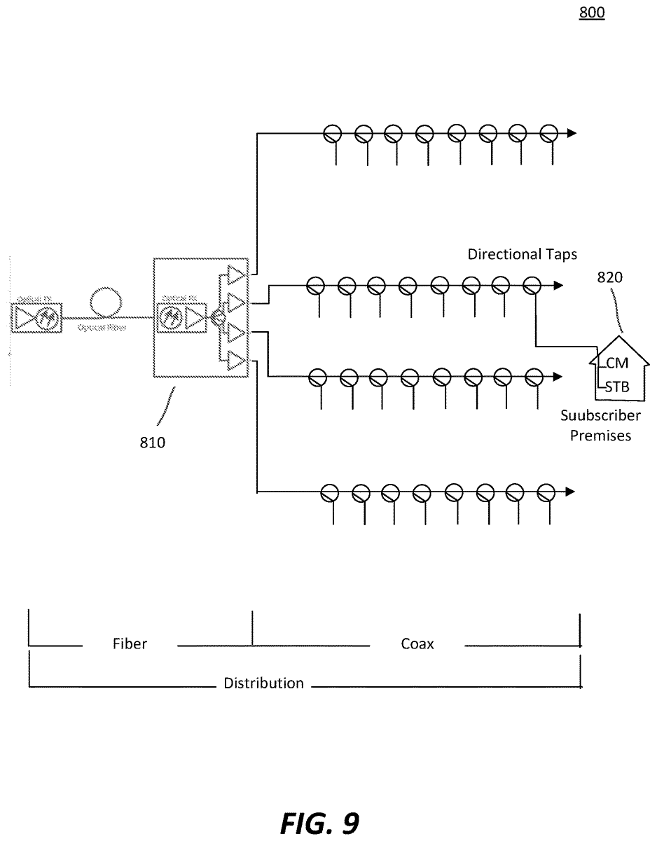

FIG. 10 shows an example of a HFC network 900 in which small cells 930 may be provided, according to some embodiments of the present disclosure. The small cells 930 may be in communication with optical nodes 910, which may provide data signals to the small cells 930, and with power sourcing equipment 940, which may provide power signals to the small cells 930.

There is also increasing interest in deploying networks of small cell base stations in existing passive optical networks (PON), which are used by some system operators, including MSOs. Powered devices, such as splitters and/or converters, in PONs may use DC power signals.

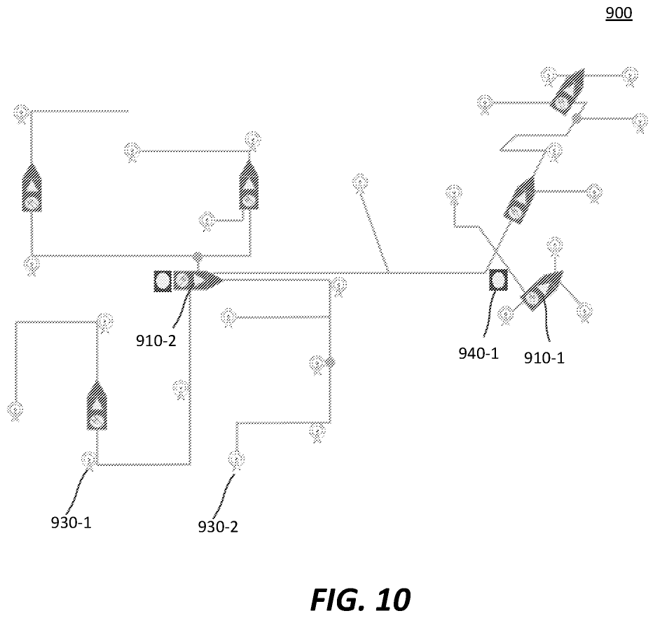

FIG. 11 provides block diagram 510, showing an arrangement of power equipment in a power plant (e.g., locations where power signals may be generated for communications equipment). In FIG. 11, for example, an AC to DC converter may provide a 48 VDC (or −48 VDC) signal to a bus tied to a 48V battery backup. The bus may be tied to a DC-DC converter that boosts the signal from 48V to 380V. An ACS and/or other power management circuit may receive the boosted signal and output a signal (e.g., a +/−190 V DC signal) resulting from a high resistance midpoint ground (HRMG) circuit or device. The bus may also be tied to an optical line terminal that services a PON.

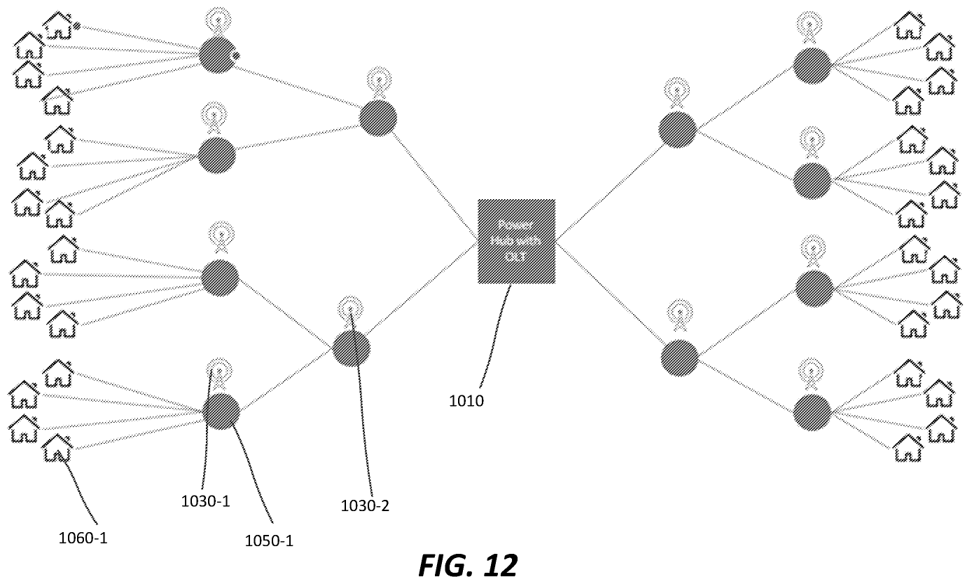

FIG. 12 shows an example of a PON 1100 in which small cells 1030 may be provided, according to some embodiments of the present disclosure. The small cells 1030 may be in communication (and colocated with) optical splitters 1050, which may provide data signals to the small cells 1030 and to customer premises 1060. The small cells 1030 may receive power signals from a power hub 1010, which may be colocated with an optical line terminal (OLT).

Some aspects of the present disclosure have been described above with reference to the accompanying drawings and materials. The present disclosure is not limited to the illustrated embodiments. Well-known functions or constructions may not be described in detail for brevity and/or clarity. As used herein the expression “and/or” includes any and all combinations of one or more of the associated listed items. It will be understood that features illustrated with one example embodiment above can be incorporated into any of the other example embodiments. Thus, it will be appreciated that the disclosed embodiments may be combined in any way to provide many additional embodiments.

It will be understood that, although the terms first, second, etc. may be used herein to describe various elements, these elements should not be limited by these terms.

These terms are only used to distinguish one element from another. For example, a first element could be termed a second element, and, similarly, a second element could be termed a first element, without departing from the scope of the present disclosure.

1. A power supply system, comprising:
a rack shelf; and
at least one card that is configured to be installed in the rack shelf, the at least one card having at least one fault managed power circuit therein.

2. The power supply system of claim 1, wherein the rack shelf comprises a plurality of openings, and wherein the at least one card is dimensioned to be received in a respective opening of the plurality of openings.

3. The power supply system of claim 2, wherein a total number of the openings of the rack shelf exceeds a number of cards installed in the rack shelf.

4. The power supply system of claim 1, wherein each of the at least one cards is configured to receive a first power signal from the rack shelf and provide a second power signal to at least one respective telecommunications component.

5. The power supply system of claim 4, wherein the first power signal is a DC power signal.

6. The power supply system of claim 4, wherein the second power signal is provided to at least one small cell base station.

7. The power supply system of claim 1, wherein the at least one card comprises a high resistance midpoint ground (HRMG) device or circuit.

8. The power supply system of claim 1, wherein the at least one card comprises a surge suppression device or circuit.

9. The power supply system of claim 1, wherein a first card of the at least one card comprises a plurality of fault managed power circuits.

10. The power supply system of claim 1, further comprising a controller configured to control operation of the fault managed power circuits.

11. The power supply system of claim 1, wherein the rack shelf is two rack units in height.

12. The power supply system of claim 1, wherein the at least one card comprises a first connector, and wherein the rack shelf comprises a second connector configured to mate with the first connector.

13. The power supply system of claim 1, wherein the rack shelf and/or the at least one card comprises a barrier interlock.

14. A power supply system, comprising:
a rack shelf comprising a plurality of openings; and
a plurality of fault managed power cards installed in respective openings in the rack shelf, each fault managed power card comprising at least one fault managed power circuit.

15. The power supply system of claim 14, wherein a total number of the plurality of openings exceeds a total number of the plurality of fault managed power cards installed in the rack shelf.

16. The power supply system of claim 14, wherein an input to the power supply system is on a rear or back surface of the rack shelf, and the outputs from the power supply system are on or proximate to a front or forward surface of the rack shelf.

17. The power supply system of claim 14, further comprising a controller configured to control operation of the fault managed power circuits, wherein the controller comprises a communication interface.

18-20. (canceled)

21. A power supply system, comprising:
an AC to DC converter having an input tied to a main power supply and an output tied to a first side of a bus;
a shelf providing fault managed power tied to a second side of the bus and configured to supply power to a cluster of small cell base stations.

22. The power supply system of claim 21, further comprising:
a DC to DC converter on the second side of the bus and configured to boost a voltage of a power signal on the bus to a higher voltage input to the shelf.

23. The power supply system of claim 22, further comprising a backup battery tied to the bus.

24-33. (canceled)
